(19) United States
(12) Patent Application Publication
(10) Pub. No.: US 2025/0333873 A1
(43) Pub. Date: Oct. 30, 2025

(54) FILM, PREPARATION METHOD THEREOF AND PHOTOELECTRIC DEVICE

(71) Applicant: Shenzhen TCL High-Tech Development Co., Ltd., Shenzhen (CN)

(72) Inventor: Jingheng WU, Shenzhen (CN)

(73) Assignee: Shenzhen TCL High-Tech Development Co., Ltd., Shenzhen (CN)

(21) Appl. No.: 19/193,873

(22) Filed: Apr. 29, 2025

(30) Foreign Application Priority Data
Apr. 30, 2024 (CN) 202410544664.8

(51) Int. Cl. C25D 11/34; H10H 20/812; H10H 20/816; H10H 20/832; H10K 50/115; H10K 50/16; H10K 50/17; H10K 50/816; H10K 50/826; H10K 102/00

(52) U.S. Cl. CPC C25D 11/34; H10H 20/812; H10H 20/8162; H10H 20/832; H10K 50/115; H10K 50/16; H10K 50/171; H10K 50/816; H10K 50/826; H10K 2102/331

(57) ABSTRACT

The present disclosure disclose a film, a preparation method thereof and a photoelectric device. A material of the film includes a first inorganic nanoparticle. The film provided by the present disclosure has few defects and high density.

This application claims priority to Chinese Application No. 202410544664.8, entitled “FILM, PREPARATION METHOD THEREOF, PHOTOELECTRIC DEVICE AND DISPLAY DEVICE”, filed on Apr. 30, 2024. The entire disclosures of the above application are incorporated herein by reference.

### TECHNICAL FIELD

The present disclosure relates to a field of display technologies, and more particularly, to film, preparation method thereof and photoelectric device.

### BACKGROUND

Inorganic nanoparticles are often used as the material of films. However, the existing films prepared by inorganic nanoparticles have many defects and poor compactness, which need to be further improved.

### Technical Solution

In view of this, the present disclosure provides a film, a preparation method thereof and a photoelectric device.

The present disclosure provides a film. A material of the film includes a first inorganic nanoparticle.

The present disclosure provides a preparation method of a film, including: providing a prefabricated film, and a material of the prefabricated film includes a second inorganic nanoparticle; and treating the prefabricated film with anodic oxidation to obtain a film, and a material of the film includes a first inorganic nanoparticle.

The present disclosure provides a photoelectric device, including: an anode; an active layer, located on the anode; a cathode, located on the active layer; and an electronic functional layer, between the active layer and the cathode, wherein the electronic functional layer comprises the film prepared by the preparation method above-mentioned.

The film provided by the present disclosure has few defects and high density.

### BRIEF DESCRIPTION OF DRAWINGS

In order to more clearly explain the technical solutions in the embodiments of the present disclosure, the following will briefly introduce the drawings required in the description of the embodiments. Obviously, the drawings in the following description are only some embodiments of the present disclosure. For those skilled in the art, without paying any creative work, other drawings could be obtained based on these drawings.

FIG. 1 is a flowchart of a method for preparing a film according to an embodiment of the present disclosure.

FIG. 2 is a schematic diagram of the structure of a film according to an embodiment of the present disclosure.

FIG. 3 is a schematic diagram of the structure of a photoelectric device according to an embodiment of the present disclosure.

### DETAILED DESCRIPTION

Technical solutions in embodiments of the present disclosure will be clearly and completely described below in conjunction with drawings in the embodiments of the present disclosure. Obviously, the described embodiments are only a part of embodiments of the present disclosure, rather than all the embodiments. Based on the embodiments in the present disclosure, all other embodiments obtained by those skilled in the art without creative work fall within the protection scope of the present disclosure.

Additionally, in the description of the present disclosure, the term “comprising/including” means “comprising/including but not limited to.” Various embodiments of the present disclosure may be presented in a form of range. It should be understood that the description in the form of range is merely for convenience and brevity, and should not be construed as a hard limitation on the scope of the disclosure. Accordingly, it should be considered that the recited range description has specifically disclosed all possible subranges, as well as a single numerical value within that range. For example, it should be considered that a description of a range from 1 to 6 has specifically disclosed subranges, such as from 1 to 3, from 1 to 4, from 1 to 5, from 2 to 4, from 2 to 6, from 3 to 6, etc., and a single number within the range, such as 1, 2, 3, 4, 5, and 6, regardless of the range. Whenever a range of values is indicated herein, it is meant to include any recited number (fraction or integer) within the indicated range.

In the present disclosure, the term “and/or” is used to describe the association of associated objects, and means that there may be three relationships, for example, “A and/or B” may refer to three cases: the first case refers to the presence of A alone; the second case refers to the presence of both A and B; the third case refers to the presence of B alone, where A and B may be singular or plural.

In the present disclosure, the term “at least one” refers to one or more, and “a plurality of/multiple” refers to two or more. The terms “at least one”, “at least one of the followings”, or the like, refer to any combination of the items listed, including any combination of the singular or the plural items. For example, “at least one of a, b, or c” or “at least one of a, b, and c” may refer to: a, b, c, a-b (i.e., a and b), a-c, b-c, or a-b-c, where a, b, and c may be single or plural.

Although inorganic nanoparticles have good transmission performance and film-forming property, the inorganic nanoparticles synthesized by the existing methods often have a large number of defects, and the process products cannot be completely converted into inorganic nanoparticles, which leads to poor uniformity of the synthesized inorganic nanoparticles. When the inorganic nanoparticles are used to make films, problems such as large particle spacing, poor particle arrangement and poor film density inevitably occur, which leads to instability of the carrier functional layer in the same pixel plane and affects the luminous efficiency, operation and storage stability of photoelectric devices.

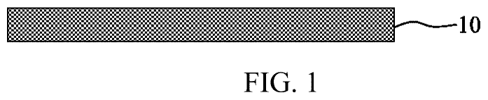

Referring to FIG. 1, the present disclosure discloses a film 10, a material of the film 10 includes a first inorganic nanoparticle.

It should be noted that when the existing inorganic nanoparticle crystals are affected by temperature rise or other external factors, some oxygen atoms may leave their original positions, resulting in oxygen deficiency and oxygen vacancies. In the process of synthesizing inorganic nanoparticles by conventional methods, it is difficult to completely react. There are raw materials, that is, metal salts, and intermediate products generated by raw materials, which will affect the purity of inorganic nanoparticles in the film, thus affecting the compactness of the film.

In the film 10 provided by this present disclosure, the first inorganic nanoparticle has high purity, low impurity content and high density, which could effectively improve the carrier mobility of the film 10, reduce the mobility difference of the film 10, and improve the service life and transmission stability of the film 10.

In some embodiments, an average particle size of the first inorganic nanoparticle ranges between 2 nm-8 nm, such as 3 nm, 4 nm, 5 nm, 6 nm, 7 nm, etc.

In some embodiments, the first inorganic nanoparticle includes a first metal oxide.

In some embodiments, the first metal oxide is selected from one or more of first doped metal oxide particle and first undoped metal oxide particle. A material of the first undoped metal oxide particle is selected from one or more of ZnO, TiO₂, SnO₂, ZrO₂ and Ta₂O₅. A metal oxide in the first doped metal oxide particle is selected from one or more of ZnO, TiO₂, SnO₂, ZrO₂, Ta₂O₅ and Al₂O₃. A doping element in the first doped metal oxide particle is selected from one or more of Al, Mg, Li, Mn, Y, La, Cu, Ni, Zr, Ce, In and Ga.

In some embodiments, the first inorganic nanoparticle has a first oxygen vacancy.

In some embodiments, in the film 10, a content of the first oxygen vacancy is not higher than 20%, for example, it could be 1%, 2%, 3%, 4%, 5%, 6%, 7%, 8%, 9%, 10%, 11%, 12%, 13%, 14%, 15%, 16%, 17%, 18% and 19%. It could be understood that it is difficult to completely remove oxygen vacancies in oxide inorganic nanoparticles, but the content of the first oxygen vacancy in the film 10 provided by this present disclosure is greatly reduced, which could avoid the problem of carrier mobility reduction of the film 10 caused by oxygen vacancy defects.

In some embodiments, a material of the film 10 further includes a first impurity. Further, the first impurity includes one or more of a first metal salt and an alkalization product of the first metal salt. It could be understood that the first metal salt is a raw material for synthesizing inorganic nanoparticle. Alkalization refers to adding alkaline substances to the reaction system. In the process of synthesizing inorganic nanoparticle, alkali needs to be added, and some metal salts react with alkali to generate alkalization product of the first metal salt. In other words, the alkalization product of the first metal salt is an incomplete reaction intermediate product in the process of synthesizing inorganic nanoparticle from raw materials. It should be noted that the film 10 may not contain the first impurity, and at this time, the performance of the film 10 is better. Due to objective reasons such as technology, it is difficult to completely remove the first impurity, resulting in a small amount of the first impurity in the film 10.

In some embodiments, in the film 10, a mass fraction of the first impurity is not higher than 10 wt %, for example, it could be 0.5 wt %, 1 wt %, 1.5 wt %, 2 wt %, 2.5 wt %, 3 wt %, 3.5 wt %, 4 wt %, 4.5 wt %, 5 wt %, 5.5 wt %, 6 wt %, 6.5 wt %, 7 wt %, 7.5 wt %, 8 wt %, 8.5 wt %, 9 wt % and 9.5 wt %. Within the mass fraction range of the first impurity, the impurity content of the film 10 is low and the performance is good.

In some embodiments, in the film 10, a mass fraction of the alkalization product of the first metal salt is not higher than 5 wt %, for example, it could be 0.5 wt %, 1 wt %, 1.5 wt %, 2 wt %, 3 wt %, 3.5 wt %, 4.5 wt %, etc.

In some embodiments, in the film 10, a mass fraction of the first metal salt is not higher than 5 wt %, for example, it could be 0.5 wt %, 1 wt %, 1.5 wt %, 2 wt %, 3 wt %, 3.5 wt %, 4.5 wt %, etc.

It could be understood that in the film 10 provided by this present disclosure, the content of the alkalization product of the first metal salt and the first metal salt are low, which could improve the purity of the first inorganic nanoparticle and further improve the carrier mobility of the film 10.

In some embodiments, the alkalization product of the first metal salt includes MAₓ(OH)_{y}, wherein M is a cation of the first metal salt and A is an anion of the first metal salt.

In some embodiments, the cation of the first metal salt is selected from one or more of zinc ion, titanium ion, tin ion, tantalum ion, zirconium ion, nickel ion, manganese ion, copper ion, indium ion, gallium ion, aluminum ion, magnesium ion, lithium ion, yttrium ion, lanthanum ion and cerium ion.

In some embodiments, the anion of the first metal salt is selected from one or more of acetate ion, sulfate ion, halide ion and nitrate ion.

In some embodiments, the alkalization product of the first metal salt is selected from one or more of Zn(AC)ₓ(OH)_{y}, Ti(AC)ₓ(OH)_{y}, Sn(AC)ₓ(OH)_{y}, Zr(AC)ₓ(OH)_{y}, Ta(AC)ₓ(OH)_{y}, Al(AC)ₓ(OH)_{y}, Li(AC)ₓ(OH)_{y}, Mn(AC)ₓ(OH)_{y}, Ga(AC)ₓ(OH)_{y}, Ti(SO₄)ₓ(OH)_{y}, Mg(SO₄)ₓ(OH)_{y}, Li(SO₄)ₓ(OH)_{y}, Ce(SO₄)ₓ(OH)_{y}, In(SO₄)ₓ(OH)_{y}, Ga(SO₄)ₓ(OH)_{y}, Zn(NO₃)ₓ(OH)_{y}, Ti(NO₃)ₓ(OH)_{y}, Sn(NO₃)ₓ(OH)_{y}, Zr(NO₃)ₓ(OH)_{y}, Y(NO₃)ₓ(OH)_{y}, La(NO₃)ₓ(OH)_{y}, Cu(NO₃)ₓ(OH)_{y}, Ni(NO₃)ₓ(OH)_{y}, Ce(NO₃)ₓ(OH)_{y}, In(NO₃)ₓ(OH)_{y}, ZnClₓ(OH)_{y}, TiClₓ(OH)_{y}, SnClₓ(OH)_{y}, MgClₓ(OH)_{y}, LiClₓ(OH)_{y}, MnClₓ(OH)_{y}, LaClₓ(OH)_{y}, CeClₓ(OH)_{y}, GaClₓ(OH)_{y}. It should be noted that the values of x and y in any of the above compounds could be independently selected due to the complex structure of the alkalized products.

In some embodiments, a thickness of the film 10 is 30 nm-100 nm, such as 40 nm, 50 nm, 60 nm, 70 nm, 80 nm, 90 nm, 95 nm, etc.

In some embodiments, a surface roughness of the film 10 is 0.5-1, such as 0.6, 0.7, 0.8, 0.9, etc. Within the range of the surface roughness, the compactness of the film 10 is high, which is beneficial to the continuous conductivity of the film 10 and promotes the carrier transmission.

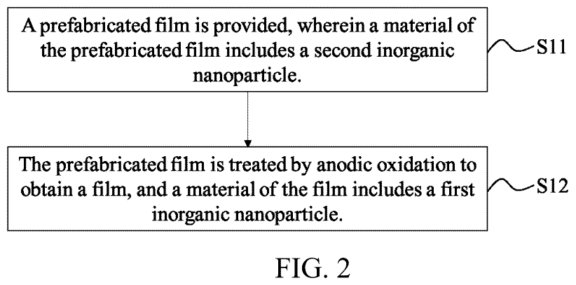

Referring to FIG. 2, the present disclosure proposes a preparation method of a film 10 which includes step S11-S12.

In step S11, a prefabricated film is provided, wherein a material of the prefabricated film includes a second inorganic nanoparticle.

In step S12, the prefabricated film is treated by anodic oxidation to obtain a film 10, and a material of the film 10 includes a first inorganic nanoparticle.

It should be noted that the anodic oxidation method refers to the electrochemical oxidation of prefabricated film containing the second inorganic nanoparticle. Specifically, the prefabricated film is used as an anode, and conventional cathode, such as magnesium, aluminium, titanium, is used, and an external current is applied in the electrolyte solution to form a passage, which promotes the further oxidation of the prefabricated film, fills the oxygen vacancies, and transforms some unconverted intermediate products into inorganic nanoparticle in one step, thus improving the compactness of the film 10.

According to the preparation method of the film 10 provided by the present disclosure, the prefabricated film is connected with the positive electrode of a power supply, and through anodic oxidation treatment, a redox reaction occurs in the electrolyte, so that oxygen vacancies could be filled, and the defects of inorganic nanoparticle could be reduced. And metal salts and their alkalized products could be further transformed into inorganic nanoparticle through oxidation, so as to achieve the effects of improving the purity of inorganic nanoparticle, reducing the impurity content and improving the density of prefabricated films. Further, the carrier mobility of the thin film 10 is improved, the mobility difference of the film 10 is reduced, and the service life and transmission stability of the film 10 are improved.

It could be understood that the preparation method of the second inorganic nanoparticle could be realized by conventional techniques in the field, such as physical method, chemical method or other method. Among them, the physical method includes mechanical ball milling, physical crushing, vacuum condensation and so on. The chemical method includes chemical reduction, photochemical method, sol-gel method, radiation reduction method, coprecipitation method, combustion synthesis method and so on. Other method includes coagulation method, blasting method, high-energy processing method, hydrothermal synthesis method, shooting synthesis method, ionization evaporation precipitation method and so on.

In some embodiments, a preparation method of the prefabricated film includes step S111-S113.

In step S111, a third metal salt, an alkali and a first solvent are provided and mixed to obtain a second inorganic nanoparticle.

In step S112, a second solvent is provided and mixed with the second inorganic nanoparticle to obtain a dispersion.

In step S113, the dispersion is deposited to obtain a prefabricated film.

In some embodiments, a cation of the third metal salt is selected from one or more of zinc ion, titanium ion, tin ion, tantalum ion, zirconium ion, nickel ion, manganese ion, copper ion, indium ion, gallium ion, aluminum ion, magnesium ion, lithium ion, yttrium ion, lanthanum ion and cerium ion.

In some embodiments, an anion of the third metal salt is selected from one or more of acetate ion, sulfate ion, halide ion and nitrate ion.

Illustratively, the third metal salt is selected from one or more of one or more of zinc acetate, zinc sulfate, zinc halide and zinc nitrate.

In some embodiments, the alkali is selected from one or more of potassium hydroxide, lithium hydroxide, sodium hydroxide, ammonium hydroxide, ethylenediamine, ethanolamine, diethanolamine, triethanolamine, tetramethylammonium hydroxide, tetraethylammonium hydroxide, tetrapropylammonium hydroxide and tetrabutylammonium hydroxide.

In some embodiments, a molar ratio of salt ions in the third metal salt to hydroxide ions in the alkali is 1:(1.5-3), such as 1:1.8, 1:2, 1:2.2, 1:2.5, 1:2.8, etc.

In some embodiments, pH of mixed solution of the third metal salt and the alkali is 12-14, such as 12.2, 12.5, 12.8, 13, 13.2, 13.5, 13.8, etc.

In some embodiments, a method for mixing the third metal salt, alkali and the first solvent includes: a third metal salt solution and an alkali solution are provided, wherein the third metal salt solution includes the third metal salt and a fourth solvent, and the alkali solution includes the alkali and a fifth solvent; and the third metal salt solution and the alkali liquor are mixed.

In some embodiments, a molar concentration of the third metal salt in the third metal salt solution ranges between 0.1 mol/L-1 mol/L, such as 0.2 mol/L, 0.3 mol/L, 0.4 mol/L, 0.5 mol/L, 0.6 mol/L, 0.7 mol/L, 0.8 mol/L and 0.9 mol/L. Within the molar concentration range, it is beneficial to the full dissolution of the third metal salt.

In some embodiments, a molar concentration of the alkali in the alkaline solution ranges between 0.1 mol/L-1 mol/L, such as 0.2 mol/L, 0.3 mol/L, 0.4 mol/L, 0.5 mol/L, 0.6 mol/L, 0.7 mol/L, 0.8 mol/L and 0.9 mol/L. Within the molar concentration range, it is beneficial to the full dissolution of the alkali.

In some embodiments, the first solvent, the second solvent, the fourth solvent and the fifth solvent are independently selected from one or more of chlorobenzene, diethylene glycol monobutyl ether, trimethoxybutanol, triethylene glycol monobutyl ether, diethylene glycol dimethyl ether, methanol, ethanol, propanol, butanol, ethylene glycol, isopropanol, glycerol, dimethyl sulfoxide, acetone, acetophenone, tetrahydrofuran, N,N-dimethylformamide, ethyl acetate, pyrrole, butyric acid and cresol.

In some embodiments, a method of mixing the third metal salt solution and the alkali solution includes: dropwise adding the alkali solution to the third metal salt solution. It could be understood that the pH could be controlled in an appropriate range by mixing in a dropping way.

The mixing of the third metal salt solution and the alkali solution may be performed at room temperature.

In some embodiments, after the third metal salt solution and the alkali solution are mixed, it further includes stirring.

Further, a time of the stirring is 1 h-4 h, such as 1.5 h, 2 h, 2.5 h, 3 h, 3.5 h, etc. In this way, it is beneficial to fully mix the third metal salt and the alkali to prepare the second inorganic nanoparticle.

In some embodiments, a mass concentration of the second inorganic nanoparticle in the dispersion ranges between 20 mg/mL-50 mg/mL, such as 22 mg/mL, 24 mg/mL, 26 mg/mL, 28 mg/mL, 30 mg/mL, 32 mg/mL, 34 mg/mL, 36 mg/mL, 38 mg/mL, 40 mg/mL, 42 mg/mL, 44 mg/mL, 46 mg/mL, 48 mg/mL, etc. In the concentration range, the dispersibility of the second inorganic nanoparticle is good, and the processability of the dispersion is good.

In some embodiments, after the dispersion is deposited, it further includes thermal annealing.

In some embodiments, a temperature of the thermal annealing is 70° C.-90° C., such as 72° C., 74° C., 76° C., 78° C., 80° C., 82° C., 84° C., 86° C., 88° C., etc. A time of the thermal annealing is 5 min-30 min, such as 5 min, 10 min, 15 min, 20 min, 25 min, etc. Thus, it is beneficial to fully remove the second solvent.

In some embodiments, the second inorganic nanoparticle has a second oxygen vacancy. A number of the first oxygen vacancy is less than a number of the second oxygen vacancy.

In some embodiments, in the prefabricated film, a content of the second oxygen vacancy is not less than 50%, for example, it could be 55%, 60%, 65%, 70%, 75%, 80%, 85%, 90%, etc. After the anodic oxidation treatment, the content of the first oxygen vacancy in the film 10 is greatly reduced, which reduces the oxygen vacancy defect, thus improving the carrier mobility of the film 10.

In some embodiments, a material of the prefabricated film further includes a second impurity. The second impurity includes one or more of a second metal salt and an alkalization product of the second metal salt.

A mass fraction of the first impurity in the film 10 is less than a mass fraction of the second impurity in the prefabricated film.

A mass fraction of the first alkalization product of the first metal salt in the film 10 is less than a mass fraction of the second alkalization product of the second metal salt in the prefabricated film.

A mass fraction of the first metal salt in the film 10 is less than a mass fraction of the second metal salt in the prefabricated film.

In some embodiments, a mass fraction of the second impurity in the prefabricated film is 25 wt %-50 wt %, such as 26 wt %, 27 wt %, 28 wt %, 29 wt %, 30 wt %, 31 wt %, 32 wt %, 33 wt %, 34 wt %, 35 wt %, 36 wt %, 37 wt %, 38 wt %, 39 wt %, 40 wt %, 41 wt %, 42 wt %, 43 wt %, 44 wt %, 45 wt %, 46 wt %, 47 wt %, 48 wt %, 49 wt %, etc. It could be understood that the content of the first impurity in the film 10 is reduced to below 10 wt %, which significantly improves the purity of the first inorganic nanoparticle in the film 10.

In some embodiments, a mass fraction of the alkalization product of the second metal salt in the prefabricated film is 15 wt %-25 wt %, such as 16 wt %, 17 wt %, 18 wt %, 19 wt %, 20 wt %, 21 wt %, 22 wt %, 23 wt %, 24 wt %, etc.

In some embodiments, a mass fraction of the second metal salt in the prefabricated film is 10%-20%, such as 11 wt %, 12 wt %, 13 wt %, 14 wt %, 15 wt %, 16 wt %, 17 wt %, 18 wt %, 19 wt %, etc.

It could be understood that both the alkalization product of the second metal salt and the second metal salt are further converted into the first inorganic nanoparticle, which improves the purity of the inorganic nanoparticle and improves the density of the film 10.

A material of the second inorganic nanoparticle refer to the first inorganic nanoparticle above, and will not be described in detail here.

In some embodiments, an average particle size of the first inorganic nanoparticle ranges between 2 nm-8 nm, such as 3 nm, 4 nm, 5 nm, 6 nm, 7 nm, etc.

Specifically, in some embodiments, the second inorganic nanoparticle includes a second metal oxide.

In some embodiments, the second metal oxide is selected from one or more of first doped metal oxide particle and first undoped metal oxide particle. A material of the first undoped metal oxide particle is selected from one or more of ZnO, TiO₂, SnO₂, ZrO₂ and Ta₂O₅. A metal oxide in the first doped metal oxide particle is selected from one or more of ZnO, TiO₂, SnO₂, ZrO₂, Ta₂O₅ and Al₂O₃. A doping element in the first doped metal oxide particle is selected from one or more of Al, Mg, Li, Mn, Y, La, Cu, Ni, Zr, Ce, In and Ga.

In some embodiments, the alkalization product of the second metal salt includes M′A′_{x′}(OH)_{y′}, wherein M′ is a cation of the second metal salt and A′ is an anion of the second metal salt.

M′ could refer to M above-mentioned, A′ could refer to A above-mentioned, and the alkalization product of the second metal salt could refer to the alkalization product of the first metal salt above-mentioned.

In some embodiments, the cation of the second metal salt is selected from one or more of zinc ion, titanium ion, tin ion, tantalum ion, zirconium ion, nickel ion, manganese ion, copper ion, indium ion, gallium ion, aluminum ion, magnesium ion, lithium ion, yttrium ion, lanthanum ion and cerium ion.

In some embodiments, the anion of the second metal salt is selected from one or more of acetate ion, sulfate ion, halide ion and nitrate ion.

In some embodiments, a surface roughness of the film 10 is less than a surface roughness of the prefabricated film.

In some embodiments, a surface roughness of the prefabricated film is 3-5, such as 3.2, 3.5, 3.8, 4, 4.2, 4.5, 4.8, etc. Within the range of the surface roughness of the prefabricated film, the compactness of the prefabricated film is low, which is prone to leakage current and is not conducive to carrier transmission. After anodic oxidation treatment, the compactness of the film 10 is improved, which is conducive to carrier transmission.

In some embodiments, the anodic oxidation treatment of the prefabricated film includes: providing electrolyte solution, placing the prefabricated film in the electrolyte solution, connecting the prefabricated film to a positive pole of a power supply, and electrifying.

In some embodiments, the electrolyte solution includes electrolyte.

The electrolyte is selected from one or more of sulfuric acid, oxalic acid, chromic acid and nitric acid.

In some embodiments, a mass concentration of the electrolyte in the electrolyte solution ranges between 5 g/L-20 g/L, such as 5 g/L, 6 g/L, 7 g/L, 8 g/L, 9 g/L, 10 g/L, 11 g/L, 12 g/L, 13 g/L, 15 g/L, 16 g/L, 17 g/L, 18 g/L, 19 g/L, etc. Within the mass concentration range, it is beneficial for the power supply to form a loop through the electrolyte and efficiently oxidize the prefabricated film.

In some embodiments, the electrolyte solution further includes a third solvent.

The third solvent includes water.

It could be understood that the connection of the prefabricated film to a positive pole of a power supply could be completed through an electrochemical workstation.

In some embodiments, a voltage of the power supply ranges between 12V-24V, such as 13V, 14V, 15V, 16V, 17V, 18V, 19V, 20V, 21V, 22V, 23V, etc.

In some embodiments, a current density of the power supply ranges between 0.5 mA/cm²-1 mA/cm², such as 0.5 mA/cm², 0.55 A/cm², 0.6 A/cm², 0.65 A/cm², 0.7 A/cm², 0.75 A/cm², 0.8 A/cm², 0.85 A/cm², 0.9 A/cm², 0.95 A/cm², etc.

In some embodiments, a time of the electrifying ranges between 30 s-60 s, such as 32 s, 34 s, 36 s, 38 s, 40 s, 42 s, 44 s, 48 s, 50 s, 52 s, 54 s, 56 s, 58 s, etc.

In some embodiments, a temperature at the time of the electrifying ranges between 20° C.-40° C., such as 22° C., 24° C., 26° C., 28° C., 30° C., 32° C., 34° C., 36° C., 38° C., etc.

In this way, within the range of voltage, current density, time and temperature of the electrifying, it is beneficial to fill the oxygen vacancy of the second inorganic nanoparticle, reduce defects and improve the density and stability of the film 10. Furthermore, the second metal salt and its alkalization products could be further converted into inorganic nanoparticle, so as to improve the purity of inorganic nanoparticle in the prefabricated film and further improve the carrier migration efficiency of the film 10.

In some embodiments, after the electrifying, it further includes: cleaning and drying.

A cleaning agent of the cleaning could be water.

A temperature of the drying ranges between 60° C.-90° C., such as 65° C., 70° C., 75° C., 80° C., 85° C., etc. A time of the drying ranges between 30 min-60 min, such as 35 min, 40 min, 45 min, 50 min, 55 min, etc. In this way, it is beneficial to fully remove the cleaning agent and the electrolyte.

It could be understood that the film 10 treated by this present disclosure does not contain or contains a very small amount of impurities such as alkalization products of metal salts and metal salts, and the oxygen vacancy content of inorganic nanoparticle drops sharply.

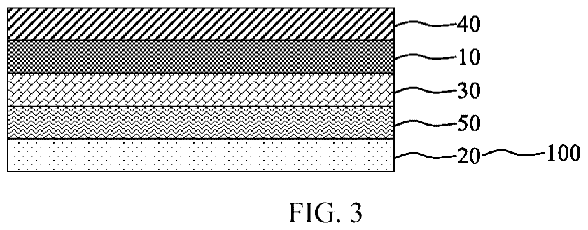

Referring to FIG. 3, the present disclosure discloses a photoelectric device 100, including:
an anode 20;
an active layer 30, located on the anode 20;
a cathode 40, located on the active layer 30; and
an electronic functional layer, between the active layer 30 and the cathode 40, wherein the electronic functional layer includes the film 10 above-mentioned or the film 10 prepared by the preparation method above-mentioned.

In the photoelectric device 100 provided by the present disclosure, the film 10 is used as the electronic functional layer, so that the density of the electronic functional layer could be improved, and the uniformity and stability in the same pixel plane could be improved. And it also could effectively improve the electron migration efficiency of the electronic functional layer, thereby improving the luminous efficiency and stability of the photoelectric device 100 and reducing the efficiency fluctuation of the photoelectric device 100.

In some embodiments, the photoelectric device 100 is a light emitting diode.

In some embodiments, the electronic functional layer includes one or more of an electron injection layer and an electron transport layer.

A material of the anode 20 and the cathode 40 is each independently selected from one or more of metal, carbon material and metal oxide. The metal is selected from one or more of Al, Ag, Cu, Mo, Au, Ba, Ca, Yb and Mg. The carbon material is selected from one or more of graphite, carbon nanotubes, graphene and carbon fiber. The metal oxide is selected from one or more of metal oxide electrode or composite electrode with metal sandwiched between doped or undoped transparent metal oxide, and a material of the metal oxide electrode is selected from one or more of ITO, FTO, ATO, AZO, GZO, IZO, MZO, MoO₃ and AMO. The composite electrode is selected from one or more of AZO/Ag/AZO, AZO/AI/AZO, ITO/Ag/ITO, ITO/AI/ITO, ZnO/Ag/ZnO, ZnO/Al/ZnO, ZnS/Ag/ZnS, ZnS/Al/ZnS, TiO₂/Ag/TiO₂ and TiO₂/Al/TiO₂. Where “/” represents a laminated structure, for example, AZO/Ag/AZO represents a composite electrode including an AZO layer, an Ag layer and an AZO layer which are sequentially laminated.

In some embodiments, the active layer 30 includes a luminescent layer, a material of the luminescent layer is luminescent material, and the luminescent material is selected from one or more of organic luminescent material and quantum dot luminescent material.

A material of the organic luminescent material is selected from one or more of CBP:Ir(mppy)₃(4,4′-bis(N-carbazole)-1,1′-biphenyl: tris [2-(p-tolyl) pyridine iridium (III)]), TCTX:Ir(mmpy)(4,4′), 4″-tris(carbazole-9-yl)triphenylamine: tris [2-(p-tolyl) iridium pyridine]), diarylanthracene derivatives, stilbene aromatic derivatives, pyrene derivatives, fluorene derivatives, TBPe fluorescent materials, TTPX fluorescent materials, TBRb fluorescent materials, DBP fluorescent materials, delayed fluorescent materials, TTA materials, TADF (delayed thermal activation) materials, polymers containing B—N covalent bonds, HLCT (hybrid local charge transfer excited state) materials and Exciplex luminescent materials.

The quantum dot luminescent material could be selected from but not limited to one or more of single-structure quantum dot, core-shell quantum dot and perovskite-type semiconductor material.

A material of the single-structure quantum dot, a core material of the core-shell quantum dot and a shell material of the core-shell quantum dot could be respectively selected from but not limited to one or more of second II-VI compound, second IV-VI compound, second III-V compound and I-III-VI compound. A shell layer of the core-shell structure quantum dot comprises one or more layers. The second II-VI compound is selected from one or more of CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe. The second IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe. The second III-V compound is selected from one or more of GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAINP, GaAINAs, GaAINSb, GaAlPAs, GaAlPSb, GaInNP, GalnNAs, GaInNSb, GalnPAs, GaInPSb, InAINP, InAINAs, InAINSb, InAlPAs and InAlPSb. The I—III-VI compound is selected from one or more of CuInS₂, CuInSe₂ and AgInS₂.

As an example, the core-shell quantum dot is selected from one or more of CdSe/CdSeS/CdS, InP/ZnSeS/ZnS, CdZnSe/ZnSe/ZnS, CdSe/ZnS, CdSe/ZnSe, ZnSe/ZnS, ZnSe/ZnS, ZnSe/ZnS, and ZnSe/ZnSe/ZnSe.

The perovskite semiconductor material is selected from one of doped or undoped inorganic perovskite semiconductor or organic-inorganic hybrid perovskite semiconductor. A general structural formula of the inorganic perovskite semiconductor is AMX₃, wherein A is Cs⁺, and X is divalent metal cation, which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, and X is a halogen anion selected from one or more of Cl⁻, Br⁻ and I⁻. The general structural formula of the organic-inorganic hybrid perovskite semiconductor is BMX₃, wherein B is an organic amine cation selected from CH₃(CH₂)ₙ₋₂NH₃⁺ or [NH₃(CH₂)ₙNH₃]²⁺, wherein n≥2, and M is a divalent metal cation selected from Pb²⁺, Sn²⁺, Cu²⁺, Ni²⁺, Cd²⁺ and Cr³⁺, and X is a halogen anion selected from one or more of Cl⁻, Br⁻ and I⁻.

In some embodiments, the photoelectric device 100 further includes a hole functional layer 50 disposed between the anode 20 and the active layer 30.

The hole functional layer 50 includes one or more of a hole injection layer and a hole transport layer.

In some embodiments, a material of the hole functional layer 50 is selected from one or more of 4,4′-N,N′-dicarbazolyl-biphenyl, N,N′-diphenyl-N,N′-bis (1-naphthyl)-1,1′-biphenyl)-4,4 ‘-diamine, N,N’-bis(3-methylphenyl)-N,N′-bis(phenyl)-spiro, N,N′-bis(4-(N,N′-diphenyl-amino)phenyl)-N,N′-diphenylbenzidine, 4,4′,4′-tris (N-carbazolyl)-triphenylamine, 4,4′,4′-tris (carbazole-9-yl) triphenylamine, trichloroisocyanuric acid, terbium-doped phosphate-based green luminescent material, 2,3,6,7,10,11-hexacyano-1,4,5,8,9,12-hexaazaphenanthrene, 4,4′,4′-tris (N-3-methylphenyl-N-phenylamino) triphenylamine, poly [(9,9′-dioctyl fluorene-2,7-diyl)-co-(4,4′-(N-(4-sec-butylphenyl)diphenylamine))], poly (4-butylphenyl-diphenylamine), poly [bis(4-phenyl) (4-butylphenyl) amine], polyaniline, polypyrrole, poly (p) phenylene vinylene, poly (phenylene vinylene), poly [2-methoxy-5-(2-ethylhexyloxy)-1,4-phenylene vinylene], poly [2-methoxy-5-(3′,7′-dimethyl octyloxy)-1,4-phenylene vinylene], copper phthalocyanine, aromatic tertiary amine, 4,4′-bis (p-carbazolyl)-1,1′-biphenyl compound, N,N,N′,N′-tetraarylbenzidine, poly(9,9-dioctylfluorene-alt-N-(4-sec-butylphenyl)-diphenylamine), PEDOT, PEDOT:PSS and its derivatives, PEDOT:PSS derivatives doped with s-MoO₃, poly (N-vinylcarbazole) and its derivatives, polymethacrylate and its derivatives, poly (9,9-octylfluorene) and its derivatives, poly (spirofluorene) and its derivatives, N,N′-bis (naphthalene-1-yl)-N,N′-diphenylbenzidine, spiro NPB, nanocrystalline diamond, microcrystalline cellulose, tetracyanoquinone dimethylmethane, doped graphene, undoped graphene, second doped metal oxide particle, second undoped metal oxide particle, metal sulfide, metal selenides and metal nitride, wherein a metal oxide in the second doped metal oxide particle and a metal oxide in the second undoped metal oxide particle is independently selected from one or more of MoO₃, WO₃, NiO, CrO₃, CuO and V₂O₅, and a doping element in the second doped metal oxide particle is selected from one or more of Mo, W, Ni, Cr, Cu and V, the metal sulfide is selected from one or more of CuS, MoS₃ and WS₃, the metal selenide is selected from one or more of MoSe₃ and WSe₃, and the metal nitride is selected from p-type gallium nitride.

The present disclosure also discloses a display device, including the photoelectric device 100 in any of the above embodiments.

The display device could be a mobile terminal such as a TV set, a mobile phone, a tablet computer, a computer monitor, or a device with a display screen such as a game device, an Augmented Reality (AR) device, a Virtual Reality (VR) device, a data storage device, an audio playback device, a video playback device, and a wearable device, wherein the wearable device could be a smart bracelet, smart glasses, and a smart watch.

This present disclosure will be explained in detail by specific examples. The following examples are only partial examples of this present disclosure, and are not limited to this present disclosure.

### Example 1

This example provides a film, and a preparation method of the film includes steps S1-S3.

In step S1, a 30 mg/mL ethanol dispersion of ZnO is provided, which is spin-coated on a substrate and annealed at 80° C. for 10 min to form a prefabricated film.

In step S2, the prefabricated membrane is connected to an anode of an electrochemical workstation, immersed in 12 g/L sulfuric acid electrolyte solution together with a cathode of the electrochemical workstation, and the electrochemical workstation is turned on at 25° C. with a voltage of 18V and a current density of 0.75 mA/cm², and energized for 45 s.

In step S3, the treated prefabricated film is taken out and washed with deionized water to remove the surface residue on the prefabricated film, dried at 80° C. for 30 min, and deionized water is removed to obtain the film.

### Example 2

This example is basically the same as Example 1, only the difference is that in this example, the voltage of the electrochemical workstation is 24V.

### Example 3

This example is basically the same as Example 1, only the difference is that in this example, the voltage of the electrochemical workstation is 12V.

### Example 4

This example is basically the same as Example 1, only the difference is that in this example, the voltage of the electrochemical workstation is 30V.

### Example 5

This example is basically the same as Example 1, only the difference is that in this example, the voltage of the electrochemical workstation is 10V.

### Example 6

This example is basically the same as Example 1, only the difference is that in this example, the current density of the electrochemical workstation is 1 mA/cm².

### Example 7

This example is basically the same as Example 1, only the difference is that in this example, the current density of the electrochemical workstation is 0.5 mA/cm².

### Example 8

This example is basically the same as Example 1, only the difference is that in this example, the current density of the electrochemical workstation is 1.5 mA/cm².

### Example 9

This example is basically the same as Example 1, only the difference is that in this example, the current density of the electrochemical workstation is 0.1 mA/cm².

### Example 10

This example is basically the same as Example 1, only the difference is that in this example, the time for the energizing of the electrochemical workstation is 60 s.

### Example 11

This example is basically the same as Example 1, only the difference is that in this example, the time for the energizing of the electrochemical workstation is 30 s.

### Example 12

This example is basically the same as Example 1, only the difference is that in this example, the time for the energizing of the electrochemical workstation is 90 s.

### Example 13

This example is basically the same as Example 1, only the difference is that in this example, the time for the energizing of the electrochemical workstation is 15 s.

### Example 14

This example is basically the same as Example 1, only the difference is that in this example, the mass concentration of the sulfuric acid electrolyte solution is 20 g/L.

### Example 15

This example is basically the same as Example 1, only the difference is that in this example, the mass concentration of the sulfuric acid electrolyte solution is 5 g/L.

### Example 16

This example is basically the same as Example 1, only the difference is that in this example, ZnO is replaced by TiO₂.

### Example 17

This example is basically the same as Example 1, only the difference is that in this example, the sulfuric acid electrolyte solution is replaced by oxalic acid electrolyte solution.

### Comparative Example 1

This comparative example provides a film which is the prefabricated film of Example 1.

### Comparative Example 2

This comparative example provides a film which is the prefabricated film of Example 16.

The oxygen vacancy, surface roughness and electron mobility of the films of Examples 1-17 and Comparative Examples 1-3 were tested, and the results are shown in Table 1.

The test method of the oxygen vacancy is to test the oxygen vacancy peak by X-ray photoelectron spectroscopy (XPS).

The surface roughness is measured by atomic force microscope (AFM).

The method for testing the electron mobility includes: testing the current density-voltage curves of the semi-devices (single carrier transport thin film devices EOD) formed by the films of Examples 1-17 and Comparative Examples 1-3 to obtain the space charge limited current (SCLC) region in the current density-voltage curve, and then calculating the electron mobility according to the formula J=(9/8) εᵣε₀μₑV²/d³. Among them, the structure of EOD is anode/quantum dot active layer/electron transport layer/cathode, the anode is made of ITO, the quantum dot active layer is made of CdSeS/ZnS, the cathode is made of Ag, and the electron transport layer is the above films. In the calculation formula, J represents the current density in mAcm⁻², εᵣ represents relative dielectric constant, ε₀ represents vacuum dielectric constant, μₑ represents electron mobility, and the unit is cm²V⁻¹s⁻¹, V represents the driving voltage in V, and d represents the film thickness in m.

TABLE 1

| | Oxygen | Surface | Electron |
|---|---|---|---|
| | vacancy | roughness | mobility |
| | (%) | (nm) | (cm²V⁻¹s⁻¹) |
| Example 1 | 12 | 0.7 | 5.74 × 10² |
| Example 2 | 11 | 0.7 | 5.24 × 10² |
| Example 3 | 13 | 0.8 | 5.11 × 10² |
| Example 4 | 15 | 0.9 | 5.08 × 10² |
| Example 5 | 14 | 0.9 | 5.02 × 10² |
| Example 6 | 13 | 0.7 | 5.36 × 10² |
| Example 7 | 12 | 0.8 | 5.47 × 10² |
| Example 8 | 14 | 1.0 | 5.07 × 10² |
| Example 9 | 14 | 0.9 | 5.06 × 10² |
| Example 10 | 13 | 0.7 | 5.34 × 10² |
| Example 11 | 12 | 0.7 | 5.30 × 10² |
| Example 12 | 15 | 1.0 | 5.11 × 10² |
| Example 13 | 14 | 0.8 | 5.06 × 10² |
| Example 14 | 12 | 0.7 | 5.75 × 10² |
| Example 15 | 13 | 0.7 | 5.71 × 10² |
| Example 16 | 12 | 0.8 | 4.85 × 10² |
| Example 17 | 11 | 0.8 | 4.27 × 10² |
| Comparative Example 1 | 68 | 3.1 | 3.47 × 10² |
| Comparative Example 2 | 71 | 3.5 | 2.74 × 10² |
| Comparative Example 3 | 64 | 3.2 | 3.11 × 10² |

From Examples 1-5 and Comparative Examples 1,3, it could be seen that the films prepared by the method provided by this present disclosure could effectively fill oxygen vacancies through oxidation and reduction, so that the alkaline product of metal salt, that is, the semi-product of inorganic nanoparticle, is fully converted into inorganic nanoparticle, which reduces the surface roughness of the film and further improves the electron migration performance of the film. The voltage of electric field has a certain influence on the properties of films. In the preferred range of voltage provided by this present disclosure, the film has fewer oxygen vacancies, lower surface roughness and higher electron mobility. Compared with Examples 1-3 which the voltage is appropriate, the performance of the films in Examples 4-5 is worse when the voltage is higher or lower. In Comparative Example 3, the metal was directly oxidized into metal oxide nanoparticles by anodic oxidation, which still had high oxygen vacancy content, high surface roughness and low electron mobility, and the performance of the film was poor.

From Examples 1, 6-9 and Comparative Example 1, it could be seen that the current density in the electric field also has a certain influence on the films. The properties of the films in Examples 1, 6-9 are all better than those in Comparative Example 1, but in Examples 8-9, higher or lower current density is adopted, and the improvement effect on the properties of the films such as oxygen vacancy, surface roughness and electron mobility is worse than that in Examples 1, 6-7. Therefore, when the current density is appropriate, the film has higher performance.

From Examples 1, 10-13 and Comparative Example 1, it could be seen that the electrifying time of the electric field will also affect the performance of the films. In Example 12, the performance of the film decreased compared with Examples 1, 10-11 because of the long electrifying time. In Example 13, the electrifying time was short, which might not fully fill the oxygen vacancy of the film and reduce the surface roughness. However. On the whole, the properties of the films of Examples 1, 10-13 are better than those of Comparative Example 1.

From Examples 1, 14-17 and Comparative Examples 1-2, the electrolyte concentration has no significant influence on the performance of the films. Compared with Comparative Example 1, Examples 1, 14-15 all have fewer oxygen vacancies, lower film surface roughness and higher electron mobility. The preparation method of the films provided by this present disclosure has wide applicability, and the films prepared by replacing electrolyte or inorganic nanoparticles have higher performance than Comparative Example 1.

### Photoelectric Device Example 1

This example provides a photoelectric device, and a preparation method of the photoelectric device includes steps S21-S27.

In step S21, an ITO substrate with patterned electrodes is provided and cleaned, and the surface of the ITO substrate is treated with ultraviolet ozone for 5 min to further remove the organic matter attached to the ITO substrate surface and improve the work function of the ITO substrate, thus an anode with a thickness of 120 nm is formed.

In step S22, a PEDOT:PSS solution is spin-coated on the anode and a molar ratio of PEDOT to PSS is 1:1, and it was annealed at 150° C. for 30 min to form a hole injection layer with a thickness of 80 nm.

In step S23, TFB solution is spin-coated on the hole injection layer and annealed at 150° C. for 20 min to form a hole transport layer with a thickness of 70 nm.

In step S24, a 30 mg/mL of n-octane dispersion of CdSeS/ZnS is provided, and an octyl mercaptan ligand is attached to the surface of the CdSeS/ZnS, and there is 0.2 mmol of the ligand in each 1 mg CdSeS/ZnS. The dispersion is spin-coated on the on the hole transport layer and annealed at 130° C. for 30 min to form a quantum dot active layer with a thickness of 70 nm.

In step S25, the film is prepared on the quantum dot active layer by the method of Example 1, and an electron transport layer with a thickness of 50 nm is formed.

In step S26, Ag is thermally evaporated on the electronic transport layer by placing it in the evaporation bin, thus a cathode with a thickness of 100 nm is formed.

In step S27, a photoelectric device is obtained after packaging.

### Photoelectric Device Examples 2-17

Photoelectric device Examples 2-17 are basically the same as Photoelectric device Example 1, and only the difference is that films are separately formed on the quantum dot active layer according to the method of Examples 2-17 to prepare electronic transport layer. Photoelectric device Comparative Examples 1-3

Photoelectric device Comparative Examples 1-3 are basically the same as photoelectric device Example 1, and only the difference is that films are separately formed on the quantum dot active layer according to the method of Comparative Examples 1-3 to prepare electronic transport layer.

The current efficiency (C.E.), service life T95@1000 nit and on/off efficiency fluctuation of Photoelectric device Examples 1-17 and Photoelectric device Comparative Examples 1-3 were tested respectively, and the results obtained are shown in Table 2.

The current efficiency is measured and calculated by Keithley 2400 high-precision digital source meter, Ocean Optical USB 2000+spectrometer and LS-160 luminometer.

When photoelectric device is driven by constant current, the time when the brightness drops to 95% of the highest brightness is defined as T95, which indicates the measured lifetime. In order to shorten the test period, the photoelectric device service life test is usually carried out by accelerating the aging of the photoelectric device under high brightness, and the service life under high brightness is obtained by fitting the extended exponential decay brightness attenuation formula, for example, the service life at 1000 nit is T95@1000 nit. The specific calculation formula is as follows:

$$T {95}_{L} = T {95}_{H} \cdot {( \frac{{L}_{H}}{{L}_{L}} )}^{A} .$$

Where T95_{L} is the service life under low brightness, T95_{H} is the measured service life under high brightness, L_{H} is the acceleration of the device to the highest brightness, L_{L} is 1000 nit, and A is the acceleration factor. In this experiment, the service life of several groups of QLED devices under rated brightness is measured and the value of A is 1.7.

The test method of on/off efficiency fluctuation is the efficiency change of photoelectric device operating at 1000 nit and restarting after 1 min of shutdown.

TABLE 2

| | | T95@ | Efficiency |
|---|---|---|---|
| | C.E. | 1000 nit | fluctuation |
| | (%) | (h) | (%) |
| Photoelectric device Example 1 | 94.7 | 33480 | 1-2 |
| Photoelectric device Example 2 | 94.2 | 33901 | 1-2 |
| Photoelectric device Example 3 | 95.1 | 32940 | 1-2 |
| Photoelectric device Example 4 | 93.2 | 31758 | 1-2 |
| Photoelectric device Example 5 | 92.9 | 31257 | 1-3 |
| Photoelectric device Example 6 | 93.7 | 32987 | 1-2 |
| Photoelectric device Example 7 | 94.8 | 32654 | 1-2 |
| Photoelectric device Example 8 | 92.8 | 31541 | 2-4 |
| Photoelectric device Example 9 | 93.1 | 31864 | 1-2 |
| Photoelectric device Example 10 | 95.1 | 31974 | 1-2 |
| Photoelectric device Example 11 | 94.2 | 32549 | 1-2 |
| Photoelectric device Example 12 | 93.4 | 31674 | 2-3 |
| Photoelectric device Example 13 | 91.9 | 30987 | 2-4 |
| Photoelectric device Example 14 | 93.8 | 33150 | 1-2 |
| Photoelectric device Example 15 | 94.1 | 32947 | 1-2 |
| Photoelectric device Example 16 | 93.4 | 32897 | 1-2 |
| Photoelectric device Example 17 | 91.5 | 31592 | 1-2 |
| Photoelectric device Comparative Example 1 | 67.2 | 23841 | 8-13 |
| Photoelectric device Comparative Example 2 | 65.7 | 20747 | 8-14 |
| Photoelectric device Comparative Example 3 | 64.7 | 21047 | 8-13 |

From Photoelectric device Examples 1-5 and Photoelectric device Comparative Examples 1, 3, applying the film provided by this present disclosure to the electronic transport layer of photoelectric devices could effectively improve the current efficiency of photoelectric devices, prolong the service life of photoelectric devices, reduce the fluctuation of operating efficiency of photoelectric devices and improve the stability of photoelectric devices. The voltage of electric field has a certain influence on the performance of films when preparing films. Compared with Photoelectric device Examples 1-3, Photoelectric device Examples 4-5 used larger or smaller voltage, which led to a slight decrease in the current efficiency and service life of photoelectric devices, and the efficiency fluctuation in Photoelectric device Example 5 increased to 1%-3%. In Photoelectric device Comparative Example 3, the electronic transport layer is prepared by anodic oxidation, and the efficiency of photoelectric device is poor, the efficiency film is high, and the performance of photoelectric device is unstable.

From Photoelectric device Examples 1, 6-9 and Photoelectric device Comparative Example 1, it could be seen that when the current density in the electric field is large or small when preparing the films in Examples 8-9, the performance of the films such as oxygen vacancy, surface roughness and electron mobility is worse than that in Examples 1, 6-7. Accordingly, the current efficiency, service life and efficiency fluctuation performance of Photoelectric device Examples 8-9 are also worse than those of Photoelectric device Examples 1, 6-7.

From Photoelectric device Examples 1, 10-13 and Photoelectric device Comparative Example 1, it could be seen that the current efficiency, service life and efficiency fluctuation performance of the photoelectric devices in Photoelectric device Examples 1, 10-13 are better than those in Photoelectric device Comparative Example 1. However, in the process of film preparation, the electrifying time of electric field is also longer or shorter, which leads to obvious changes in the efficiency fluctuation of photoelectric devices. The efficiency fluctuation of Photoelectric device Examples 12-13 increased to 2%-3% and 2%-4% respectively, and the stability was worse.

From Photoelectric device Examples 1, 14-17 and Photoelectric device Comparative Examples 1-2, it could be seen that the current efficiency of Photoelectric device Examples 1, 14-17 is obviously improved, the service life is also prolonged, and the efficiency fluctuation is obviously reduced, and it is stable between 1%-2%. The photoelectric device provided by the present disclosure has high stability and photoelectric performance.

Film, preparation method thereof and photoelectric device are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of present disclosure in accordance with the teachings of the present disclosure. In view of the foregoing, the content of the present specification should not be construed as limiting the disclosure.

What is claimed is:

1. A film, wherein a material of the film comprises a first inorganic nanoparticle.

2. The film according to claim 1, wherein an average particle size of the first inorganic nanoparticle ranges between 2 nm-8 nm;
the first inorganic nanoparticle comprises a first metal oxide;
the first inorganic nanoparticle has a first oxygen vacancy;
a material of the film further comprises a first impurity, and the first impurity comprises one or more of a first metal salt and an alkalization product of the first metal salt; and
a thickness of the film is 30 nm-100 nm.

3. The film according to claim 2, wherein the film is obtained by anodic oxidation treatment of a prefabricated film, and a material of the prefabricated film comprises a second inorganic nanoparticle.

4. The film according to claim 3, wherein an average particle size of the second inorganic nanoparticle ranges between 2 nm-8 nm;
the second inorganic nanoparticle comprises a second metal oxide;
the second inorganic nanoparticle has a second oxygen vacancy; and
a material of the prefabricated film further comprises a second impurity, and the second impurity comprises one or more of a second metal salt and an alkalization product of the second metal salt.

5. The film according to claim 4, wherein a number of the first oxygen vacancy is less than a number of the second oxygen vacancy;
a mass fraction of the first impurity in the film is less than a mass fraction of the second impurity in the prefabricated film;
a mass fraction of the first alkalization product of the first metal salt in the film is less than a mass fraction of the second alkalization product of the second metal salt in the prefabricated film;
a mass fraction of the first metal salt in the film is less than a mass fraction of the second metal salt in the prefabricated film; and
a surface roughness of the film is less than a surface roughness of the prefabricated film.

6. The film according to claim 4, wherein a content of the first oxygen vacancy is not higher than 20%, and a content of the second oxygen vacancy is not less than 50%;
a mass fraction of the first impurity is not higher than 10 wt %, and a mass fraction of the second impurity in the prefabricated film is 25 wt %-50 wt %;
a mass fraction of the alkalization product of the first metal salt is not higher than 5 wt %, and a mass fraction of the alkalization product of the second metal salt in the prefabricated film is 15 wt %-25 wt %;
a mass fraction of the first metal salt is not higher than 5 wt %, and a mass fraction of the second metal salt in the prefabricated film is 10%-20%; and
a surface roughness of the film is 0.5-1, and a surface roughness of the prefabricated film is 3-5.

7. The film according to claim 4, wherein the first metal oxide and the second metal oxide are independently selected from one or more of first doped metal oxide particle and first undoped metal oxide particle, and a material of the first undoped metal oxide particle is selected from one or more of ZnO, TiO₂, SnO₂, ZrO₂ and Ta₂O₅, and a metal oxide in the first doped metal oxide particle is selected from one or more of ZnO, TiO₂, SnO₂, ZrO₂, Ta₂O₅ and Al₂O₃, and a doping element in the first doped metal oxide particle is selected from one or more of Al, Mg, Li, Mn, Y, La, Cu, Ni, Zr, Ce, In and Ga.

8. The film according to claim 4, wherein the alkalization product of the first metal salt comprises MAₓ(OH)_{y}, wherein M is a cation of the first metal salt and A is an anion of the first metal salt; the alkalization product of the second metal salt comprises M′A′_{x′}(OH)_{y′}, wherein M′ is a cation of the second metal salt and A′ is an anion of the second metal salt;
M and M′ are independently selected from one or more of zinc ion, titanium ion, tin ion, tantalum ion, zirconium ion, nickel ion, manganese ion, copper ion, indium ion, gallium ion, aluminum ion, magnesium ion, lithium ion, yttrium ion, lanthanum ion and cerium ion;
A and A′ are independently selected from one or more of acetate ion, sulfate ion, halide ion and nitrate ion; and
the alkalization product of the first metal salt and the alkalization product of the second metal salt are independently selected from one or more of Zn(AC)ₓ(OH)_{y}, Ti(AC)ₓ(OH)_{y}, Sn(AC)ₓ(OH)_{y}, Zr(AC)ₓ(OH)_{y}, Ta(AC)ₓ(OH)_{y}, Al(AC)ₓ(OH)_{y}, Li(AC)ₓ(OH)_{y}, Mn(AC)ₓ(OH)_{y}, Ga(AC)ₓ(OH)_{y}, Ti(SO₄)ₓ(OH)_{y}, Mg(SO₄)ₓ(OH)_{y}, Li(SO₄)ₓ(OH)_{y}, Ce(SO₄)ₓ(OH)_{y}, In(SO₄)ₓ(OH)_{y}, Ga(SO₄)ₓ(OH)_{y}, Zn(NO₃)ₓ(OH)_{y}, Ti(NO₃)ₓ(OH)_{y}, Sn(NO₃)ₓ(OH)_{y}, Zr(NO₃)ₓ(OH)_{y}, Y(NO₃)ₓ(OH)_{y}, La(NO₃)ₓ(OH)_{y}, Cu(NO₃)ₓ(OH)_{y}, Ni(NO₃)ₓ(OH)_{y}, Ce(NO₃)ₓ(OH)_{y}, In(NO₃)ₓ(OH)_{y}, ZnClₓ(OH)_{y}, TiClₓ(OH)_{y}, SnClₓ(OH)_{y}, MgClₓ(OH)_{y}, LiClₓ(OH)_{y}, MnClₓ(OH)_{y}, LaClₓ(OH)_{y}, CeClₓ(OH)_{y}, GaClₓ(OH)_{y}.

9. A preparation method of a film, comprising:
providing a prefabricated film, and a material of the prefabricated film comprises a second inorganic nanoparticle; and
treating the prefabricated film with anodic oxidation to obtain a film, and a material of the film comprises a first inorganic nanoparticle.

10. The preparation method according to claim 9, wherein an average particle size of the first inorganic nanoparticle and an average particle size of the second inorganic nanoparticle range independently between 2 nm-8 nm;
the second inorganic nanoparticle comprises a second metal oxide, and the first inorganic nanoparticle comprises a first metal oxide;
the second inorganic nanoparticle has a second oxygen vacancy, and the first inorganic nanoparticle has a first oxygen vacancy; and
a material of the prefabricated film further comprises a second impurity, and the second impurity comprises one or more of a second metal salt and an alkalization product of the second metal salt; and a material of the film further comprises a first impurity, and the first impurity comprises one or more of a first metal salt and an alkalization product of the first metal salt.

11. The preparation method according to claim 10, wherein a number of the first oxygen vacancy is less than a number of the second oxygen vacancy;
a mass fraction of the first impurity in the film is less than a mass fraction of the second impurity in the prefabricated film;
a mass fraction of the first alkalization product of the first metal salt in the film is less than a mass fraction of the second alkalization product of the second metal salt in the prefabricated film;
a mass fraction of the first metal salt in the film is less than a mass fraction of the second metal salt in the prefabricated film; and
a surface roughness of the film is less than a surface roughness of the prefabricated film.

12. The preparation method according to claim 9, wherein a content of the first oxygen vacancy is not higher than 20%, and a content of the second oxygen vacancy is not less than 50%;
a mass fraction of the first impurity is not higher than 10 wt %, and a mass fraction of the second impurity in the prefabricated film is 25 wt %-50 wt %;
a mass fraction of the alkalization product of the first metal salt is not higher than 5 wt %, and a mass fraction of the alkalization product of the second metal salt in the prefabricated film is 15 wt %-25 wt %;
a mass fraction of the first metal salt is not higher than 5 wt %, and a mass fraction of the second metal salt in the prefabricated film is 10%-20%; and
a surface roughness of the film is 0.5-1, and a surface roughness of the prefabricated film is 3-5.

13. The preparation method according to claim 10, wherein the first metal oxide and the second metal oxide are independently selected from one or more of first doped metal oxide particle and first undoped metal oxide particle, and a material of the first undoped metal oxide particle is selected from one or more of ZnO, TiO₂, SnO₂, ZrO₂ and Ta₂O₅, and a metal oxide in the first doped metal oxide particle is selected from one or more of ZnO, TiO₂, SnO₂, ZrO₂, Ta₂O₅ and Al₂O₃, and a doping element in the first doped metal oxide particle is selected from one or more of Al, Mg, Li, Mn, Y, La, Cu, Ni, Zr, Ce, In and Ga;
the alkalization product of the first metal salt comprises MAₓ(OH)_{y}, wherein M is a cation of the first metal salt and A is an anion of the first metal salt; the alkalization product of the second metal salt comprises M′A′_{x′}(OH)_{y′}, wherein M′ is a cation of the second metal salt and A′ is an anion of the second metal salt; M and M′ are independently selected from one or more of zinc ion, titanium ion, tin ion, tantalum ion, zirconium ion, nickel ion, manganese ion, copper ion, indium ion, gallium ion, aluminum ion, magnesium ion, lithium ion, yttrium ion, lanthanum ion and cerium ion; A and A′ are independently selected from one or more of acetate ion, sulfate ion, halide ion and nitrate ion; and
the alkalization product of the first metal salt and the alkalization product of the second metal salt are independently selected from one or more of Zn(AC)ₓ(OH)_{y}, Ti(AC)ₓ(OH)_{y}, Sn(AC)ₓ(OH)_{y}, Zr(AC)ₓ(OH)_{y}, Ta(AC)ₓ(OH)_{y}, Al(AC)ₓ(OH)_{y}, Li(AC)ₓ(OH)_{y}, Mn(AC)ₓ(OH)_{y}, Ga(AC)ₓ(OH)_{y}, Ti(SO₄)ₓ(OH)_{y}, Mg(SO₄)ₓ(OH)_{y}, Li(SO₄)ₓ(OH)_{y}, Ce(SO₄)ₓ(OH)_{y}, In(SO₄)ₓ(OH)_{y}, Ga(SO₄)ₓ(OH)_{y}, Zn(NO₃)ₓ(OH)_{y}, Ti(NO₃)ₓ(OH)_{y}, Sn(NO₃)ₓ(OH)_{y}, Zr(NO₃)ₓ(OH)_{y}, Y(NO₃)ₓ(OH)_{y}, La(NO₃)ₓ(OH)_{y}, Cu(NO₃)ₓ(OH)_{y}, Ni(NO₃)ₓ(OH)_{y}, Ce(NO₃)ₓ(OH)_{y}, In(NO₃)ₓ(OH)_{y}, ZnClₓ(OH)_{y}, TiClₓ(OH)_{y}, SnClₓ(OH)_{y}, MgClₓ(OH)_{y}, LiClₓ(OH)_{y}, MnClₓ(OH)_{y}, LaClₓ(OH)_{y}, CeClₓ(OH)_{y}, GaClₓ(OH)_{y}.

14. The preparation method according to claim 9, wherein the treating the prefabricated film with anodic oxidation comprises: providing electrolyte solution, placing the prefabricated film in the electrolyte solution, connecting the prefabricated film to a positive pole of a power supply, and electrifying.

15. The preparation method according to claim 14, wherein a voltage of the power supply ranges between 12V-24V; a current density of the power supply ranges between 0.5 mA/cm²-1 mA/cm²; a time of the electrifying ranges between 30 s-60 s; and a temperature at the time of the electrifying ranges between 20° C.-40° C.

16. The preparation method according to claim 14, wherein the electrolyte solution comprises electrolyte, the electrolyte is selected from one or more of sulfuric acid, oxalic acid, chromic acid and nitric acid, and a mass concentration of the electrolyte in the electrolyte solution ranges between 5 g/L-20 g/L;
the electrolyte solution further comprises a third solvent, and the third solvent comprises water; and
after the electrifying, it further comprises: cleaning and drying; a cleaning agent of the cleaning is water; a temperature of the drying ranges between 60° C.-90° C., and a time of the drying ranges between 30 min-60 min.

17. The preparation method according to claim 9, wherein a preparation method of the prefabricated film comprising:
providing and mixing a third metal salt, an alkali and a first solvent to obtain a second inorganic nanoparticle;
providing a second solvent and mixing with the second inorganic nanoparticle to obtain a dispersion; and
depositing the dispersion to obtain a prefabricated film.

18. The preparation method according to claim 17, wherein a cation of the third metal salt is selected from one or more of zinc ion, titanium ion, tin ion, tantalum ion, zirconium ion, nickel ion, manganese ion, copper ion, indium ion, gallium ion, aluminum ion, magnesium ion, lithium ion, yttrium ion, lanthanum ion and cerium ion; and an anion of the third metal salt is selected from one or more of acetate ion, sulfate ion, halide ion and nitrate ion;
the alkali is selected from one or more of potassium hydroxide, lithium hydroxide, sodium hydroxide, ammonium hydroxide, ethylenediamine, ethanolamine, diethanolamine, triethanolamine, tetramethylammonium hydroxide, tetraethylammonium hydroxide, tetrapropylammonium hydroxide and tetrabutylammonium hydroxide;
the first solvent and the second solvent are independently selected from one or more of chlorobenzene, diethylene glycol monobutyl ether, trimethoxybutanol, triethylene glycol monobutyl ether, diethylene glycol dimethyl ether, methanol, ethanol, propanol, butanol, ethylene glycol, isopropanol, glycerol, dimethyl sulfoxide, acetone, acetophenone, tetrahydrofuran, N,N-dimethylformamide, ethyl acetate, pyrrole, butyric acid and cresol;
a molar ratio of salt ions in the third metal salt to hydroxide ions in the alkali is 1:(1.5-3);
pH of mixed solution of the third metal salt and the alkali is 12-14;
a mass concentration of the second inorganic nanoparticle in the dispersion ranges between 20 mg/mL-50 mg/mL; and
after the depositing the dispersion, further comprising: thermal annealing; and a temperature of the thermal annealing is 70° C.-90° C., a time of the thermal annealing is 5 min-30 min.

19. A photoelectric device, comprising:
an anode;
an active layer, located on the anode;
a cathode, located on the active layer; and
an electronic functional layer, between the active layer and the cathode, wherein the electronic functional layer comprises a film, and a material of the film comprises a first inorganic nanoparticle.

20. The photoelectric device according to claim 19, wherein a material of the first electrode and the second electrode is each independently selected from one or more of metal, carbon material and metal oxide, and the metal is selected from one or more of Al, Ag, Cu, Mo, Au, Ba, Ca, Yb and Mg, and the carbon material is selected from one or more of graphite, carbon nanotubes, graphene and carbon fiber, and the metal oxide is selected from one or more of metal oxide electrode or composite electrode with metal sandwiched between doped or undoped transparent metal oxide, and a material of the metal oxide electrode is selected from one or more of ITO, FTO, ATO, AZO, GZO, IZO, MZO, MoO₃ and AMO, and the composite electrode is selected from one or more of AZO/Ag/AZO, AZO/AI/AZO, ITO/Ag/ITO, ITO/AI/ITO, ZnO/Ag/ZnO, ZnO/Al/ZnO, ZnS/Ag/ZnS, ZnS/Al/ZnS, TiO₂/Ag/TiO₂ and TiO₂/Al/TiO₂;
the active layer comprises a luminescent layer, a material of the luminescent layer is luminescent material, and the luminescent material is selected from one or more of organic luminescent material and quantum dot luminescent material; and a material of the organic luminescent material is selected from one or more of CBP:Ir(mppy)₃, TCTX:Ir(mmpy), diarylanthracene derivatives, stilbene aromatic derivatives, pyrene derivatives, fluorene derivatives, TBPe fluorescent materials, TTPX fluorescent materials, TBRb fluorescent materials, DBP fluorescent materials, delayed fluorescent materials, TTA materials, TADF materials, polymers containing B—N covalent bonds, HLCT materials and Exciplex luminescent materials, and the quantum dot luminescent material is selected from one or more of single-structure quantum dot, core-shell quantum dot and perovskite-type semiconductor material; a material of the single-structure quantum dot, a core material of the core-shell quantum dot and a shell material of the core-shell quantum dot could be respectively selected from but not limited to one or more of second II-VI compound, second IV-VI compound, second III-V compound and I-III-VI compound; and a shell layer of the core-shell structure quantum dot comprises one or more layers; the second II-VI compound is selected from one or more of CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe; the second IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe; the second III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb; the I-III-VI compound is selected from one or more of CuInS₂, CuInSe₂ and AgInS₂; and the core-shell quantum dot is selected from one or more of CdSe/CdSeS/CdS, InP/ZnSeS/ZnS, CdZnSe/ZnSe/ZnS, CdSe/ZnS, CdSe/ZnSe, ZnSe/ZnS, ZnSe/ZnS, ZnSe/ZnS, and ZnSe/ZnSe/ZnSe; and the perovskite semiconductor material is selected from one of doped or undoped inorganic perovskite semiconductor or organic-inorganic hybrid perovskite semiconductor; a general structural formula of the inorganic perovskite semiconductor is AMX₃, wherein A is Cs⁺, and X is divalent metal cation, which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, and X is a halogen anion selected from one or more of Cl⁻, Br⁻ and I⁻; the general structural formula of the organic-inorganic hybrid perovskite semiconductor is BMX₃, wherein B is an organic amine cation selected from CH₃(CH₂)ₙ₋₂NH₃⁺ or [NH₃(CH₂)ₙNH₃]²⁺, wherein n≥2, and M is a divalent metal cation selected from Pb²⁺, Sn²⁺, Cu²⁺, Ni²⁺, Cd²⁺ and Cr³⁺, and X is a halogen anion selected from one or more of Cl⁻, Br⁻ and I⁻; and
the photoelectric device further comprises a hole functional layer disposed between the anode and the active layer, a material of the hole functional layer is selected from one or more of 4,4′-N,N′-dicarbazolyl-biphenyl, N,N′-diphenyl-N,N′-bis (1-naphthyl)-1,1′-biphenyl)-4,4′-diamine, N,N′-bis (3-methylphenyl)-N,N′-bis (phenyl)-spiro, N,N′-bis (4-(N,N′-diphenyl-amino)phenyl)-N,N′-diphenylbenzidine, 4,4′,4′-tris (N-carbazolyl)-triphenylamine, 4,4′,4′-tris (carbazole-9-yl) triphenylamine, trichloroisocyanuric acid, terbium-doped phosphate-based green luminescent material, 2,3,6,7,10,11-hexacyano-1,4,5,8,9,12-hexaazaphenanthrene, 4,4′,4′-tris (N-3-methylphenyl-N-phenylamino) triphenylamine, poly [(9,9′-dioctyl fluorene-2,7-diyl)-co-(4,4′-(N-(4-sec-butylphenyl)diphenylamine))], poly (4-butylphenyl-diphenylamine), poly [bis (4-phenyl) (4-butylphenyl) amine], polyaniline, polypyrrole, poly (p) phenylene vinylene, poly (phenylene vinylene), poly [2-methoxy-5-(2-ethylhexyloxy)-1,4-phenylene vinylene], poly [2-methoxy-5-(3′,7′-dimethyl octyloxy)-1,4-phenylene vinylene], copper phthalocyanine, aromatic tertiary amine, 4,4′-bis (p-carbazolyl)-1,1′-biphenyl compound, N,N,N′,N′-tetraarylbenzidine, poly(9,9-dioctylfluorene-alt-N-(4-sec-butylphenyl)-diphenylamine), PEDOT, PEDOT:PSS and its derivatives, PEDOT:PSS derivatives doped with s-MoO3, poly (N-vinylcarbazole) and its derivatives, polymethacrylate and its derivatives, poly (9,9-octylfluorene) and its derivatives, poly (spirofluorene) and its derivatives, N,N′-bis (naphthalene-1-yl)-N,N′-diphenylbenzidine, spiro NPB, nanocrystalline diamond, microcrystalline cellulose, tetracyanoquinone dimethylmethane, doped graphene, undoped graphene, second doped metal oxide particle, second undoped metal oxide particle, metal sulfide, metal selenides and metal nitride, wherein a metal oxide in the second doped metal oxide particle and a metal oxide in the second undoped metal oxide particle is independently selected from one or more of MoO₃, WO₃, NiO, CrO₃, CuO and V₂O₅, and a doping element in the second doped metal oxide particle is selected from one or more of Mo, W, Ni, Cr, Cu and V, the metal sulfide is selected from one or more of CuS, MoS₃ and WS₃, the metal selenide is selected from one or more of MoSe₃ and WSe₃, and the metal nitride is selected from p-type gallium nitride.
